(19) United States
(12) Patent Application Publication
(10) Pub. No.: US 2009/0237887 A1
(43) Pub. Date: Sep. 24, 2009

(54) ELECTRONIC DEVICE

(75) Inventor: Manabu SHIBATA, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/371,660

(22) Filed: Feb. 16, 2009

(30) Foreign Application Priority Data
Feb. 15, 2008 (JP) 2008-034394

(51) Int. Cl. H05K 7/20

(52) U.S. Cl. 361/709

(57) ABSTRACT

An electronic device includes a circuit board on which a device generating heat in an operation state is mounted, a chassis to accommodate the circuit board, and a temperature-responsive arrangement. The chassis includes a holding part. The temperature-responsive arrangement extends and contracts in accordance with temperature so as to dispose the device apart from the holding part at a first temperature less than a threshold temperature, and to dispose the device in contact with the holding part at a second temperature exceeding the threshold temperature.

### CROSS-REFERENCE TO RELATED APPLICATION

This application is based upon and claims the benefit of priority of prior Japanese Patent Application No. 2008-34394, filed on Feb. 15, 2008, the entire contents of which are incorporated herein by reference.

### FIELD

Embodiments of the present invention relate to an electronic device in which a device generating heat in the operation state is accommodated in a chassis.

### BACKGROUND

In an electronic device installed outdoors, electronic parts are generally accommodated in a chassis in order to protect the electronic device from, for example, rainwater and dust. However, in the outdoor electronic device, the temperature in the chassis is easily increased by heat generated from the electronic parts and direct exposure to sunlight, for example. The likelihood of an increase in temperature in an outdoor electronic device is greater than the likelihood of an increase in temperature of an indoor device. The increase in temperatures may result in damage to the outdoor electronic device. Therefore, a radiation mechanism with high cooling effect such as a cooling fin is usually provided in the chassis of an outdoor electronic device. Heat generated from the electronic parts is absorbed by a heat pipe or the like to be transmitted to the radiation mechanism, whereby the inside of the chassis is cooled.

Additionally, it is assumed that the outdoor electronic device is used under high temperature. On the other hand, it is also assumed that the electronic device is used under low temperature such as below freezing, for example. In fact, the electronic device used outdoors may be required to normally operate under the environment of about −40° C. However, the usual electronic part requires temperature of about 0° C. to normally operate. Heat obtained by self-heating is drawn away by the radiation mechanism with high cooling effect, and therefore, a sufficient temperature may not be obtained when the environmental temperature is lower, whereby an operation failure of the electronic device may occur during operation, or the electronic parts of the electronic device may be damaged by malfunction. Especially, when the electronic device is turned on, the temperature in the chassis is reduced to the same level as the environmental temperature; therefore, there is a problem that the electronic part cannot be started.

In view of the above problem, an apparatus for automatically opening and closing a ventilating hole is described in Japanese Patent Laid-Open Publication No. 11-307970 (hereinafter, patent document 1). In this related apparatus, a ventilating hole for allowing external air in a chassis to cool the inside of the chassis is provided, and it is opened and closed by using bimetal deformed in accordance with change of heat, for example. According to the related apparatus, the ventilating hole is closed in a low temperature state, and therefore, the inside of the chassis may be cooled by opening the ventilating hole only at high temperature, and, at the same time, it is possible to alleviate a problem of rainwater entering the chassis through the ventilating hole.

However, the inside of the chassis at high temperature may not be satisfactorily cooled only by opening and closing the ventilating hole in accordance with the environment temperature, and the temperature in the chassis at low temperature may not be increased to a specified temperature at which the electronic part can normally operate. Therefore, it is considered preferable that a heat pipe, a heater, and the like are used together in the apparatus described in the patent document 1, the heat generated from the electronic part at high temperature is absorbed by the heat pipe to be efficiently dissipated, and the electronic part at low temperature is heated by the heater.

However, even if the electronic part at low temperature is heated by the heater, the heat itself applied to the electronic part is dissipated outside the chassis through the heat pipe, and therefore, there is a problem that it takes time to satisfactorily increase the temperature of the electronic part, or the electric power consumed by the heater is increased to increase the operational cost.

### SUMMARY

At least in part due to the above issues of related technologies, embodiments discussed herein provide an electronic device which may efficiently regulate the temperature in the chassis while reducing the electric power consumption.

An example of an embodiment provides an electronic device. The electronic device includes a circuit board on which a device generating heat in an operation state is mounted; a chassis to accommodate the circuit board and including a holding part; and at least one temperature-responsive arrangement to extend and contract in accordance with temperature so as to dispose the device apart from the holding part at a first temperature less than a threshold temperature, and to dispose the device in contact with the holding part at a second temperature exceeding the threshold temperature.

An example of an embodiment provides an electronic device. The electronic device includes a circuit board on which a device generating heat in an operation state is mounted; a chassis to accommodate the circuit board and including a holding part; and a displacement machine to substantially, thermally couple/decouple the holding part and the device according to ambient temperature.

An example of an embodiment provides an electronic device. The electronic device includes a circuit board on which a device generating heat in an operation state is mounted; a chassis to accommodate the circuit board and including a holding part; and a displacement machine to selectively change a heat transfer mode of the device from a conductive mode to a convective mode based on a temperature within the chassis.

According to an aspect of the embodiments, an electronic device disclosed includes a chassis which accommodates a circuit board on which a device generating heat in an operation state is mounted, has a holding part coming in contact with the device to absorb heat from the device, and radiates the heat from the device, and a temperature-responsive arrangement which extends and contracts in accordance with temperature so that while the device is spaced from the holding part at a temperature not more than a given temperature, the device is in contact with the holding part at a temperature exceeding the given temperature.

Additional objects and advantages of the embodiments will be set forth in part in the description which follows, and in part will be obvious from the description, or may be learned by practice of the embodiments. The object and advantages of the embodiments will be realized and attained by means of the elements and combinations particularly pointed out in the appended claims.

It is to be understood that both the foregoing summary description and the following detailed description are explanatory as to some embodiments of the present invention, and not restrictive of the present invention as claimed.

### BRIEF DESCRIPTION OF THE DRAWINGS

Embodiments are illustrated by way of example and not limited by the following figures.

FIG. 1 is an outline diagram of a communication device;

FIG. 2 is a transmission diagram illustrating an inside of a box;

FIG. 3 is a view illustrating a first support part and a second support part;

FIG. 4 is a view illustrating extension and contraction of the first and second support parts due to temperature change;

FIG. 5 is a cross-sectional view of the box according to a high temperature condition;

FIG. 6 is a cross-sectional view of the box according to a low temperature condition;

FIG. 7 is a transmission diagram illustrating the inside of the box in the low temperature condition;

FIGS. 8A and 8B are views illustrating a first support part and a second support part in a second embodiment;

FIG. 9 is a view illustrating a first support part in a third embodiment; and

FIG. 10 is a cross-sectional view of the box in the third embodiment.

### DETAILED DESCRIPTION OF EXAMPLES OF EMBODIMENTS

In the figures, dimensions and/or proportions may be exaggerated for clarity of illustration. It will also be understood that when an element is referred to as being “connected to” another element, it may be directly connected or indirectly connected, i.e., intervening elements may also be present. Further, it will be understood that when an element is referred to as being “between” two elements, it may be the only element layer between the two elements, or one or more intervening elements may also be present. Like reference numerals refer to like elements throughout.

Hereinafter, examples of embodiments of the disclosed electronic device is described with reference to the drawings.

### FIRST EMBODIMENT

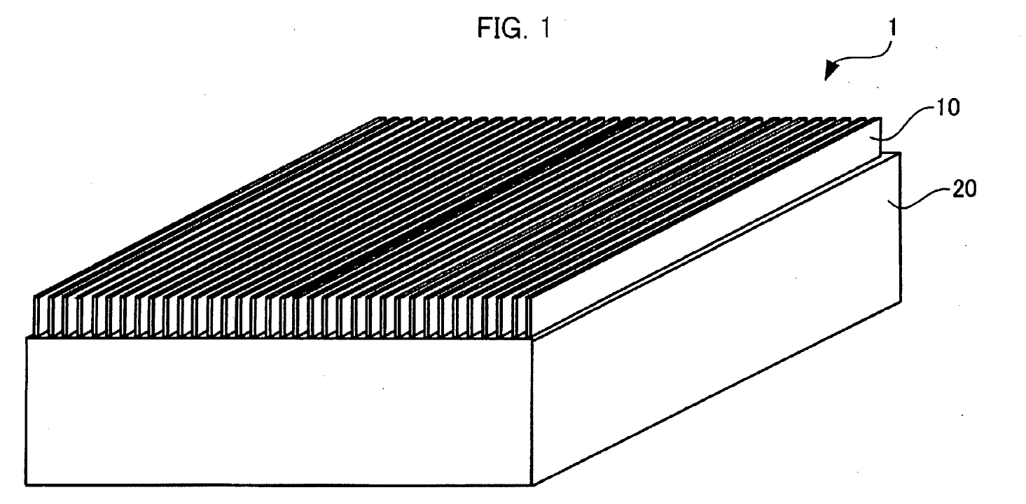

FIG. 1 is an outline diagram of a communication device 1 which is a specific first embodiment of the disclosed electronic device.

The communication device 1 is installed outdoors. The communication device 1 may include an enclosure such as a box 20, for example. A circuit board and the like and a cooling fin 10 for dissipating heat in the box 20 by coming in contact with the box 20 may be accommodated in the box 20.

The box 20 includes various devices for executing a function as the communication device 1. In the communication device 1, the temperature in the box 20 may be increased by heat generated from the device during its operation and direct exposure to sunlight. Therefore, when the temperature in the box 20 is high, heat generated in the device is transmitted to the cooling fin 10, and the inside of the box 20 should be cooled. On the other hand, when the temperature in the box 20 is low, the temperature in the box 20 should be rapidly increased to a given temperature at which the device may operate normally operate.

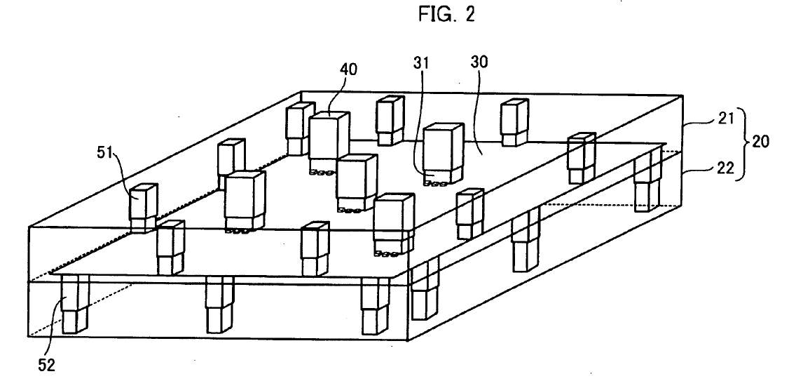

FIG. 2 is a diagram illustrating the inside of the box 20. The box 20 includes an upper lid part 21 and a bottom part 22. A plurality of second support parts 52 extending and contracting in a substantially vertical direction in accordance with temperature may be fixed to the bottom part 22. A circuit board 30 on which a plurality of devices 31 are mounted may be supported from a lower side by the second support parts 52. The device 31 corresponds to an example of a device of the disclosed electronic device, and the circuit board 30 corresponds to an example of a circuit board of the disclosed electronic device.

Meanwhile, a plurality of first support parts 51 extending and contracting in a parallel, but opposite direction to the second support part 52 in accordance with temperature may be fixed to the upper lid part 21 and press the circuit board 30 from the upper side. Namely, the circuit board 30 is supported from the top and bottom sides by being sandwiched between the first support part 51 and the second support part 52, and the first support part 51 and the second support part 52 extend and contract in opposite directions to each other in accordance with temperature, whereby the circuit board 30 is moved in the upward and downward directions. The first support part 51 and the second support part 52 correspond to an example of a temperature-responsive arrangement, or in other words a temperature change element, of the disclosed electronic device. Accordingly, the first support part 51 and the second support part 52 are examples of displacement machines for moving the circuit board 30 and components arranged thereon.

In the temperature change element of this embodiment, at least one of the first support part 51 and the second support part 52, which support the circuit board 30 from the top and bottom sides so as to sandwich the circuit board 30 therebetween, extends and contracts in accordance with temperature. Therefore, the circuit board 30 may be moved by a simple mechanism without using electric power.

Further, in the temperature change element, a pair of the first and second support parts 51 and 52 extend and contract in opposite directions to each other in accordance with temperature. Therefore, a variation in an extension and contraction characteristic of the temperature change element may be absorbed, whereby the circuit board 30 may be stably moved in accordance with temperature.

A holding part 40 which is provided so that a part of the box 20 protrudes and is in contact with the device 31 may be fixed onto the upper surface of the upper lid part 21. The holding part 40 corresponds to an example of a holding part in the basic configuration of the above electronic device.

FIG. 2 illustrates a state that the temperature in the box 20 is higher than a specified and/or threshold temperature. In FIG. 2, the circuit board 30 is moved to a position at which the device 31 is in contact with the holding part 40, and the heat generated in the device 31 is transmitted to the cooling fin 10 (see FIG. 1) by the holding part 40, whereby the inside of the box 20 is cooled.

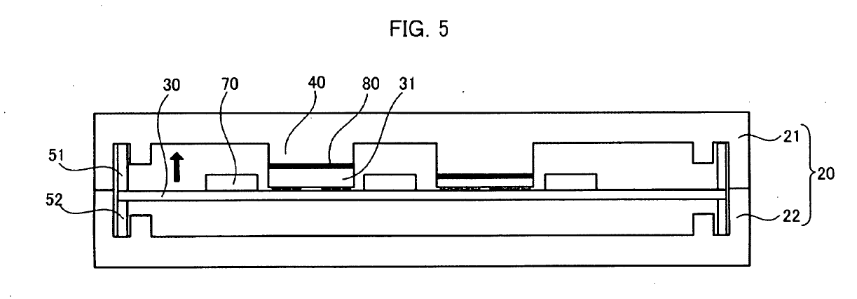

Although a heater 70 (see FIG. 5) for heating the device 31 at low temperature and other elements are disposed in the box 20, the illustration of the heater 70, for example, is omitted in FIG. 2 for the sake of clarity.

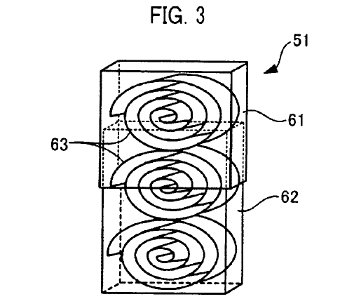

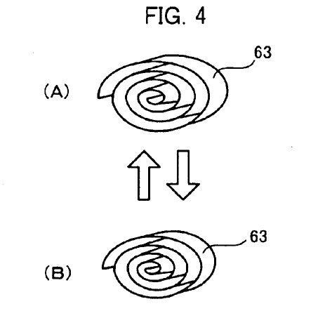

FIG. 3 depicts an example of a first support part 51. It is noted that the second support part 52 has a similar structure. FIG. 4 is a view illustrating the extension and contraction of the first and second support parts 51 and 52 due to temperature change.

Referring to FIG. 3, in the first support part 51, a plurality of coil springs 63 that extend and contract in accordance with temperature are accommodated in two boxes 61 and 62, nested inside one another, so as to be stacked in a vertical direction, for example. The coils springs 63 include a bimetal that extends and contracts in accordance with temperature. The coil spring 63 corresponds to an example of a bimetal component in the embodiment of the disclosed electronic device, and at the same time, corresponds to an example of a plurality of coil springs in the embodiment of the disclosed electronic device.

In the bimetal component, two kinds of metal plates having a coefficient of thermal extension different from each other are bonded to each other. For example, the characteristics of the two kinds of metal plates respectively extend with the increase in temperature, and the metal plate having a relatively higher coefficient of thermal extension more significantly extends, whereby the entire bimetal component is warped. An inexpensive bimetal component that curves according to temperature may be used as the temperature change element, whereby the circuit board may be moved while reducing the manufacturing cost as compared with related technologies. In addition, the plurality of coil springs may be stacked in extension and contraction directions, whereby the amount of extension and contraction of the temperature change element may be increased, and the circuit board may be reliably moved.

As illustrated in FIG. 3, the coil springs 63 extending and contracting in opposite directions to each other in accordance with a temperature change are accommodated in the first support part 51 and the second support part 52. In the present embodiment, the coil springs, which extend in the up and down directions as illustrated from (B) to (A) in FIG. 4 when temperature is decreased, are accommodated in the first support part 51 for supporting the circuit board 30 from the upper side on which the holding part 40 is provided. Meanwhile, the coil springs, which contract in the up and down directions as illustrated from (B) to (A) in FIG. 4 when temperature is decreased, are accommodated in the second support part 52 for supporting the circuit board 30 from below.

The circuit board 30 is supported by the first support part 51 and the second support part 52. Each of the first support part 51 and the second support part 52 include the bimetal which is a metal material, whereby the electric potential at required positions between the box 20 and the circuit board 30 is standardized to be able to improve the resistance against emission/immunity. The first support part 51 and the second support part 52 include the coil springs 63, whereby vibration applied to the box 20 is decreased, and the resistance against the vibration may be improved.

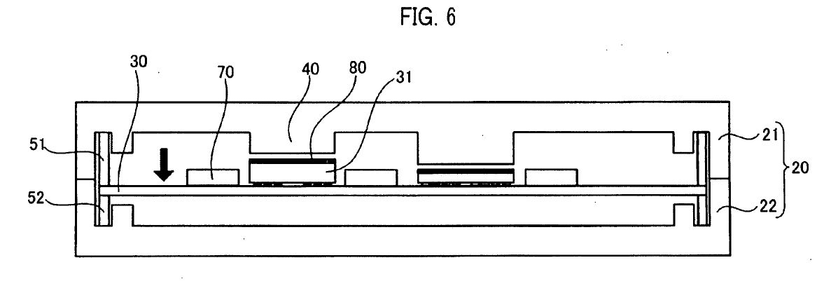

FIG. 5 is a cross-sectional view corresponding to the box 20 being cut in the vertical direction (e.g., up and down directions) in high temperature conditions. FIG. 6 is a cross-sectional view corresponding to the box 20 being cut in the up and down directions in low temperature conditions.

The heater 70 for heating the device 31 at low temperature is attached to the side of the device 31 of the circuit board 30, and heat dissipation rubber 80 for transmitting heat to the holding part 40 is applied onto the upper surface of the device 31.

As illustrated in FIG. 5, in the state that the temperature in the box 20 is higher than a specified and/or threshold temperature, the first support part 51 pressing the circuit board 30 from above contracts, and the second support part 52 pressing the circuit board 30 from below extends, whereby the circuit board 30 is moved upward. As a result, the device 31 is pressed against the holding part 40 through the heat dissipation rubber 80, and the heat generated in the device 31 is absorbed by the holding part 40 to be dissipated from the cooling fin 10 illustrated in FIG. 1. The extension and contraction amount of the first support part 51 and the second support part 52 is changed in accordance with temperature. For example, if the temperature is higher, the heat dissipation rubber 80 applied to the device 31 is more strongly pressed against the holding part 40 to increase the degree of adhesion and the contact pressure, whereby a heat radiation rate may be regulated in response to temperature. The first support part 51 and the second support part 52 include a plurality of the coil springs 63 stacked in the up and down directions to increase the movement amount of the circuit board 30. The first support part 51 and the second support part 52 extend and contract in opposite directions to each other in accordance with temperature, and the first support part 51 and the second support part 52 are provided at a plurality of positions to absorb the difference in characteristics of the bimetal included in the coil spring 63 to provide stable support for the circuit board 30.

When the temperature in the box 20 is lower than the specified and/or threshold temperature, as illustrated in FIG. 6, the first support part 51 pressing the circuit board 30 from above extends, and the second support part 52 pressing the circuit board 30 from below contracts, whereby the circuit board 30 is moved downward, and the device 31 is separated from the holding part 40. As a result, an air layer is provided between the device 31 and the holding part 40, and the heat dissipation by the holding part 40 is reduced.

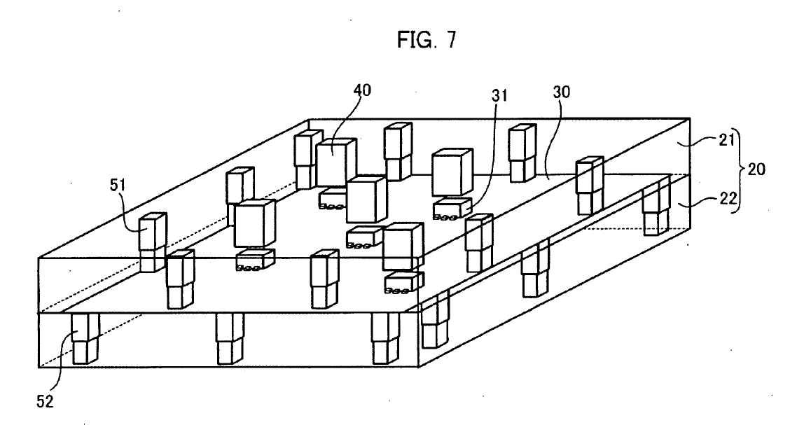

FIG. 7 is a transmission diagram illustrating the inside of the box 20 in low temperature conditions.

As illustrated in FIG. 7, in the state that the temperature in the box 20 is less than a specified and/or threshold temperature, the circuit board 30 is moved downward to a position below the position of the circuit board 30 in the high temperature state illustrated in FIG. 2. Accordingly, in the state that the temperature is less than the specified and/or threshold temperature, the device 31 is spaced from the holding part 40. When heat is generated from the heater 70 illustrated in FIG. 6, the device 31 is heated without the heat being drawn away by the holding part 40, and therefore, the temperature in the box 20 may be increased without requiring as much electric power consumption as is consumed according to related technologies.

As the bimetal of the coil spring 63 illustrated in FIG. 4, inver (an alloy of nickel and iron) may be applied as a metal material having a relatively low coefficient of thermal expansion, and an alloy of nickel, stainless steel, copper, and so on may be used as a metal material having a relatively high coefficient of thermal expansion.

For example, the bimetal with a length of about 100 mm is formed in a shape of a coil with a radius of about 8 mm, whereby a warpage of about 0.14 mm is generated per one coil due to a temperature change of about 70° C. between −30° C. and 40° C. As a result, the contraction of about 0.26 mm is obtained in the diameter of the one coil.

The four above-mentioned coils are stacked to thereby generate a fluctuation of about 1 mm on the whole, and further, the coils having these characteristics are curved in opposite directions to each other to be respectively disposed on the front and rear surface sides of the circuit board 30, whereby the circuit board 30 may be moved upwards and downwards.

As described above, according to the present embodiment, in the state that the temperature in the box 20 is larger than a specified and/or threshold temperature, heat generated during the operation and heat due to direct exposure to sunlight are dissipated by the device 31 being in contact with the holding part 40, whereby it is possible to reduce the likelihood of damage to or breakage of the device 31 due to high temperature. When the temperature in the box 20 is not more than the specified and/or threshold temperature, the device 31 is displaced from the holding part 40 to thereby reduce the heat dissipation by the holding part 40, and the device 31 may be efficiently heated by the heater 70, whereby the likelihood of operation failure and malfunction under a low temperature environment may be reduced.

Namely, while a heat conductivity of air is about 0.0241 [W/m·K], the heat conductivity of iron is 83.5 [W/m·K], and the heat conductivity of aluminum alloy is 100 to 250 [W/m·K]; thus, thermal resistance of air is considerably larger than metal widely used as a heat sink.

At this time, according to the present embodiment, when the temperature in the box 20 exceeds a specified and/or threshold temperature, the device 31 is in contact with the holding part 40, whereby the heat generated in the device 31 is absorbed by the holding part 40 to be dissipated outside the box 20. Meanwhile, when the temperature in the box 20 is less than the specified and/or threshold temperature, the circuit board 30 is moved, whereby the device 31 is spaced apart from the holding part 40. Therefore, an air layer with large thermal resistance is sandwiched between the device 31 and the holding part 40 at low temperature, whereby it is possible to reduce a problem that heat generated in the device 31 and heat applied to the device 31 by the heater 70 are dissipated outside the box 20. Accordingly, the temperature in the box 20 may be efficiently regulated.

### SECOND EMBODIMENT

A second embodiment of the disclosed electronic device will be described. The same components as those in the first embodiment are assigned the same reference numerals and description of the same components are omitted for the sake of brevity. Differences between the first embodiment and the second embodiment will be described below.

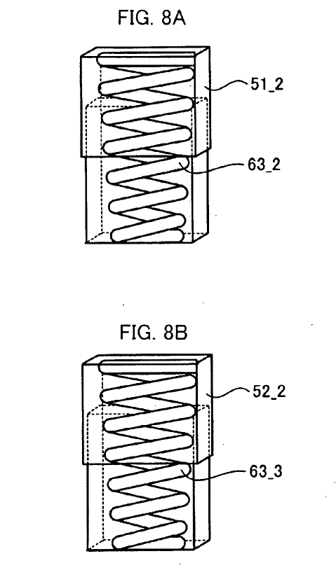

FIGS. 8A and 8B are views illustrating a first support part 51_2 and a second support part 52_2 according to the second embodiment.

As illustrated in FIG. 8A, the first support part 51_2 in which a first spring 63_2 made of a shape memory alloy is accommodated is provided instead of the first support part 51 in which the coil springs 63 made of bimetal illustrated in FIG. 3 are accommodated. The shape memory alloy is highly deformed at a specified and/or threshold temperature. The first spring 63_2 has a characteristic that the elastic force and the spring modulus become smaller with increasing temperature. The first spring 63_2 corresponds to an example of a shape memory alloy in the embodiment of the disclosed electronic device.

As described above, the shape memory alloy deformed by the temperature change is used as the temperature change element. Accordingly, a circuit board may be moved by a simple mechanism without using electric power. In addition, the spring of the shape memory alloy has a characteristic that the spring modulus varies in accordance with temperature. Thus, the spring of the shape memory alloy is used as the temperature change element, whereby the circuit board may be significantly moved.

As illustrated in FIG. 8B, the second support part 52_2 for supporting the circuit board 30 from the lower side includes a second spring 63_3. The second spring 63_3 may be formed of stainless steel and have a spring modulus that changes less, according to the temperature change, than the first spring 63_2. The second spring 63_3 is accommodated in the second support part 52_2. The second spring 63_3 corresponds to an example of an elastic member in the embodiment of the disclosed electronic device.

As described above, in the pair of the support parts 51_2 and 52_2, the first support part 51_2 is the temperature change element extending and contracting in accordance with temperature, and the second support part 52_2 is an elastic member absorbing the extension and contraction of the temperature change element, whereby the circuit board 30 may be reliably moved in accordance with temperature.

When the temperature in the box 20 illustrated in FIG. 2 increases, the spring modulus of the first spring 63_2 supporting the circuit board 30 from above reduces. As a result, the force with which the first spring 63_2 presses the circuit board 30 downward becomes smaller than the force with which the second spring 63_3 presses the circuit board 30 upward, whereby the first support part 51_2 contracts, and the second support part 52_2 extends. At this time, the circuit board 30 is moved upward, whereby the device 31 is pressed against the holding part 40. The heat of the device 31 is absorbed by the holding part 40 to be dissipated from the cooling fin 10 illustrated in FIG. 1.

Meanwhile, when the temperature in the box 20 decreases, the spring modulus of the first spring 63_2 increases, the first support part 51_2 extends, and the second support part 52_2 contracts, whereby the circuit board 30 is pressed downward. As a result, the circuit board 30 is spaced apart from the holding part 40, and the heat dissipation of the device 31 is reduced.

The first support part 51_2 and the second support part 52_2 in the second embodiment illustrated in FIGS. 8A and 8B may provide a larger amount of movement based on temperature than the first support part 51 and the second support part 52 using the coil springs 63 formed of bimetal of FIG. 3. Therefore, the distance between the circuit board 30 and the holding part 40 may be significantly increased at low temperature, whereby the heat dissipation of the device 31 may be reliably reduced.

### THIRD EMBODIMENT

A third embodiment of the disclosed electronic device will be described. The same components as those in the first and second embodiments are assigned the same reference numerals and description thereof is omitted for the sake of brevity. Differences from the second embodiment will be described below.

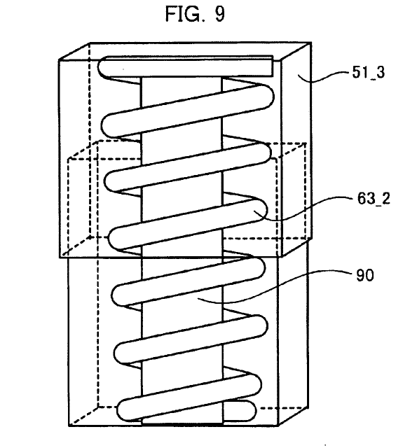

FIG. 9 is a view illustrating a first support part 51_3 in the present embodiment.

As with the first support part 51_2 of the second embodiment illustrated in FIG. 8A, the first spring 63_2 formed of a shape memory alloy is accommodated in the first support part 51_3 in the present embodiment. Further, a stopper 90 for limiting the extension and contraction amount of the first support part 51_3 is inserted into the center of the first spring 63_2. The stopper 90 may include a material with small compression. For example, the stopper 90 may include metal, plastic, glass, and other materials. The stopper 90 corresponds to an example of a stopper in the embodiment of the disclosed electronic device.

The stopper 90 limits the extension and contraction amount of the temperature change element. The stopper 90 may be used to prevent the circuit board 30 from colliding with the box 20.

When the temperature in the box 20 illustrated in FIG. 2 increases, the spring modulus of the first spring 63_2 accommodated in the first support part 51_3 reduces, and the first support part 51_3 is contracted by the bias force of the second spring 63_2 accommodated in the second support part 52_2 illustrated in FIG. 8B, whereby the circuit board 30 is moved upward. At this time, since the contraction amount of the first support part 51_3 is limited by the stopper 90, the movement amount of the circuit board 30 in the upward direction is also limited, whereby it is possible to avoid the problem that the device 31 is too strongly pressed against the holding part 40, which may result in damage to the device 31.

### FOURTH EMBODIMENT

A fourth embodiment of the disclosed electronic device will be described. Since the fourth embodiment has substantially the same constitution as the first embodiment, only differences from the first embodiment will be described.

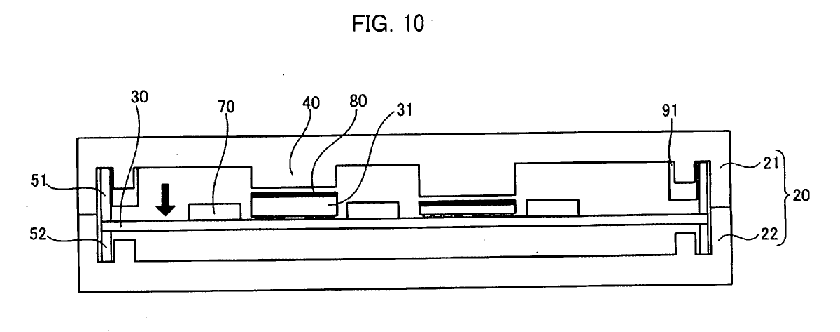

FIG. 10 is a cross-sectional view corresponding to the box 20 illustrated in FIG. 2 being cut in the vertical direction.

Also in the present embodiment, as with the first embodiment illustrated in FIG. 5, the circuit board 30, the first support part 51, the second support part 52, the holding part 40, the device 31, the heater 70, and the like are accommodated in the box 20. Further, a stopper 91 extending downward is attached to the upper lid part 21 of the box 20.

When the temperature in the box 20 increases, the first support part 51 contracts, and the second support part 52 extends, whereby the circuit board 30 is moved in the upward direction, and the device 31 is pressed against the holding part 40. At this time, since the movement of the circuit board 30 is limited by the stopper 91, the device 31 may be prevented from being pressed too hard against the holding part 40 and being damaged.

According to the above, the stopper 91 is attached not to the inside of the first support part 51, but to the box 20, whereby the device 31 may be reliably prevented from being damaged.

As described above, according to the electronic devices of the first to fourth embodiments, the temperature in the chassis may be efficiently regulated without while reducing the electric power consumption.

In the first to fourth embodiments, a displacement machine is provided (e.g., the supporting members) that includes an engine for converting thermal energy into mechanical force or motion. Examples of the engines in the first to fourth embodiment include a shape memory alloy spring and a bimetal coil spring.

In the first to fourth embodiments, although a communication device is illustrated as an example of the disclosed electronic device, this electronic device may be other devices such as a server device to be installed outdoors, for example. In addition, in the first to fourth embodiments, although the bar-like stopper with small extension and contraction is provided in the center of the spring or in the chassis, a spring for limiting the extension and contraction amount of a support member may be used as the stopper, for example. Further, in the first to fourth embodiments, although an example in which the coil spring is formed of bimetal is described, the bimetal component may be formed in a leaf spring shape, and deflection may be utilized, for example. Still further, in the first to fourth embodiments, although an example in which the cooling fin is provided in the chassis is described, a heat pipe as a radiation mechanism may be provided in the chassis, or water cooling may be used instead of air cooling, for example.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments have been described in detail, it should be understood that the various changes, substitutions, and alterations could be made hereto without departing from the spirit and scope of the invention.

1. An electronic device comprising:
a circuit board on which a device generating heat in an operation state is mounted;
a chassis to accommodate the circuit board and including a holding part; and
at least one temperature-responsive arrangement to extend and contract in accordance with temperature so as to dispose the device apart from the holding part at a first temperature less than a threshold temperature, and to dispose the device in contact with the holding part at a second temperature exceeding the threshold temperature.

2. The electronic device according to claim 1, further comprising:
a pair of support members to support the circuit board,
wherein at least one of the pair of support members includes the at least one temperature-responsive arrangement.

3. The electronic device according to claim 2, wherein a first support member of the pair contacts the circuit board on a first side and a second support member of the pair contact the circuit board on a second side opposite to the first side.

4. The electronic device according to claim 1, wherein the at least one temperature-responsive arrangement includes a bimetal component having a physical characteristic that changes according to temperature.

5. The electronic device according to claim 1, wherein the at least one temperature-responsive arrangement includes a bimetal component arranged as a coil spring.

6. The electronic device according to claim 1, wherein each of the at least one temperature-responsive arrangement includes a plurality of coil springs in a stacked arrangement.

7. The electronic device according to claim 1, wherein the temperature-responsive arrangement includes a shape memory alloy.

8. The electronic device according to claim 7, wherein the temperature-responsive arrangement includes a spring.

9. The electronic device according to claim 2, wherein the pair of support members extend and contract in parallel but opposite directions to each other in accordance with temperature.

10. The electronic device according to claim 2, wherein a first support member of the pair of support members includes the at least one temperature-responsive arrangement, and a second support member of the pair includes an elastic member to absorb extension and contraction of the at least one temperature-responsive arrangement.

11. The electronic device according to claim 1, further comprising:
a stopper to limit an amount of extension and contraction of the temperature-responsive arrangement.

12. The electronic device according to claim 11, wherein the at least one temperature-responsive arrangement includes a spring of shape memory alloy, and the stopper is disposed within an interior of the spring.

13. The electronic device according to claim 11, wherein the stopper is arranged on the chassis and limits an amount of pressure applied to the device.

14. The electronic device according to claim 1, further comprising:
a heat dissipating component configured to contact the holding part and dissipate heat absorbed by the holding part from the device when in contact with the holding part.

15. The electronic device according to claim 1, further comprising:
a heater to raise a temperature within the chassis.

16. An electronic device comprising:
a circuit board on which a device generating heat in an operation state is mounted;
a chassis to accommodate the circuit board and including a holding part; and
a displacement machine to substantially, thermally couple/decouple the holding part and the device according to ambient temperature.

17. The electronic device according to claim 16, wherein the displacement machine includes an engine, the engine includes a bimetal component having a physical characteristic that changes according to temperature.

18. The electronic device according to claim 17, wherein the bimetal component is a coil spring.

19. The electronic device according to claim 16, wherein the displacement machine includes an engine, the engine includes a shape memory alloy having a physical characteristic that changes according to temperature.

20. An electronic device comprising:
a circuit board on which a device generating heat in an operation state is mounted;
a chassis to accommodate the circuit board and including a holding part; and
a displacement machine to selectively change a heat transfer mode of the device from a primarily conductive mode to a primarily convective mode based on a temperature within the chassis.
